(19) United States
(12) Patent Application Publication
(10) Pub. No.: US 2011/0239081 A1
(43) Pub. Date: Sep. 29, 2011

(54) SEMICONDUCTOR STORAGE DEVICE AND METHOD FOR CONTROLLING A SEMICONDUCTOR STORAGE DEVICE

(75) Inventors: Toshikatsu Hida, Kanagawa (JP); Kouji Watanabe, Kanagawa (JP)

(73) Assignee: Kabushiki Kaisha Toshiba, Tokyo (JP)

(21) Appl. No.: 12/887,875

(22) Filed: Sep. 22, 2010

(30) Foreign Application Priority Data
Mar. 23, 2010 (JP) 2010-066682

(51) Int. Cl. H03M 13/29; G06F 11/10

(52) U.S. Cl. 714/755; 714/758; 714/E11.032

(57) ABSTRACT

According to one embodiment, write data is written in a nonvolatile semiconductor memory with a first error correction code and a second error correction code attached to the write data. The first error correction code and the write data are read out from the nonvolatile semiconductor memory to perform first error correction processing. When there is a remaining error, the second error correction code corresponding to the write data is read out to carry out second error correction processing.

### CROSS-REFERENCE TO RELATED APPLICATIONS

This application is based upon and claims the benefit of priority from the prior Japanese Patent Application No. 2010-066682, filed on Mar. 23, 2010; the entire contents of which are incorporated herein by reference.

### FIELD

Embodiments described herein relate generally to a semiconductor storage device and a method for controlling a semiconductor storage device.

### BACKGROUND

In a semiconductor storage device that stores information using a nonvolatile semiconductor memory, it is likely that an error occurs in data because of aged deterioration. There is a semiconductor storage device employing error check and correct (ECC) in two stages to suppress power consumption and secure a correction ability while improving an average of correction speed for such an error (see, for example, Japanese Patent Application Laid-Open No. 2009-59422 and Japanese Patent Application Laid-Open No. 2009-80651).

### BRIEF DESCRIPTION OF THE DRAWINGS

FIG. 1 is a diagram of a configuration example of a semiconductor storage device according to a first embodiment;

FIG. 2 is a diagram of a configuration example of an L1/L2 encoder;

FIG. 3 is a diagram for explaining a concept of ECC processing in two stages;

FIG. 4 is a diagram of an example of a page format according to the first embodiment;

FIG. 5 is a flowchart for explaining an example of a procedure of L2ECC code readout determination processing;

FIG. 6 is a diagram of an example of a page format according to a second embodiment;

FIG. 7 is a diagram of a configuration example of an L1/L2 encoder according to the second embodiment;

FIG. 8 is a flowchart for explaining an example of a procedure of L2ECC code readout determination processing according to the second embodiment;

FIG. 9 is a diagram of an example of a page format according to a third embodiment;

FIG. 10 is a diagram of a configuration example of a semiconductor storage device according to a fourth embodiment; and

FIG. 11 is a flowchart for explaining an example of a procedure of readout and determination processing according to the fourth embodiment.

### DETAILED DESCRIPTION

The semiconductor storage device employing the ECC in two stages stores, for each predetermined data unit, an L1ECC code generated by ECC encoding processing at a level 1 (L1) and an L2ECC code generated by ECC encoding processing at a level 2 (L2) in a semiconductor memory together with data. In reading out data, the semiconductor storage device performs detection of an error and error correction processing for the read-out data referring to the L1ECC code (L1 error correction processing). When the error cannot be corrected by the L1 error correction processing, the semiconductor storage device performs error correction processing using the L2ECC code (L2ECC processing).

The semiconductor storage device employing the ECC in two stages simultaneously reads out, in reading out the data, the L1ECC code and the L2ECC code corresponding to the data read out for each predetermined data unit. On the other hand, in general, such a semiconductor storage device simultaneously stores an error detection code for error detection for the read-out data. When it is determined based on the error detection code that there is no error in the data (there is no error in the read-out data) and when the number of errors in the read-out data is within a correction ability of the L1 error correction processing, the semiconductor storage device does not carry out the L2ECC processing. In such a case, the L2ECC code is discarded without being used. Therefore, the semiconductor storage device employing the ECC in two stages has a problem in that readout speed falls because unnecessary information not in use is read out.

In general, according to one embodiment, a semiconductor storage device writes, in a nonvolatile semiconductor memory, write data having a predetermined size, an error detection code generated to detect an error in the write data, a first error correction code generated to correct an error in first encoding target data including the write data and the error detection code corresponding to the write data, and a second error correction code generated to correct an error in a second encoding target data including a singularity or a plurality of the first encoding target data. The semiconductor storage device carries out first error correction processing for the write data using the write data, the error detection code, and the first error correction code read out from the nonvolatile semiconductor memory and determines whether there is an error remaining in the write data after the first error correction processing. The semiconductor storage device carries out second error correction processing for the write data using the second encoding target data including the write data determined as having the remaining error and the second error correction code read out from the nonvolatile semiconductor memory. The semiconductor storage device determines, based on a determination result in the first error correction processing for the write data in the second encoding target data, whether the second error correction code corresponding to the second encoding target data is read out from the nonvolatile semiconductor memory. The semiconductor storage device controls, based on a result of the determination, readout from the nonvolatile semiconductor memory.

Exemplary embodiments of a semiconductor storage device and a method for controlling a semiconductor storage device will be explained below in detail with reference to the accompanying drawings. The present invention is not limited to the following embodiments.

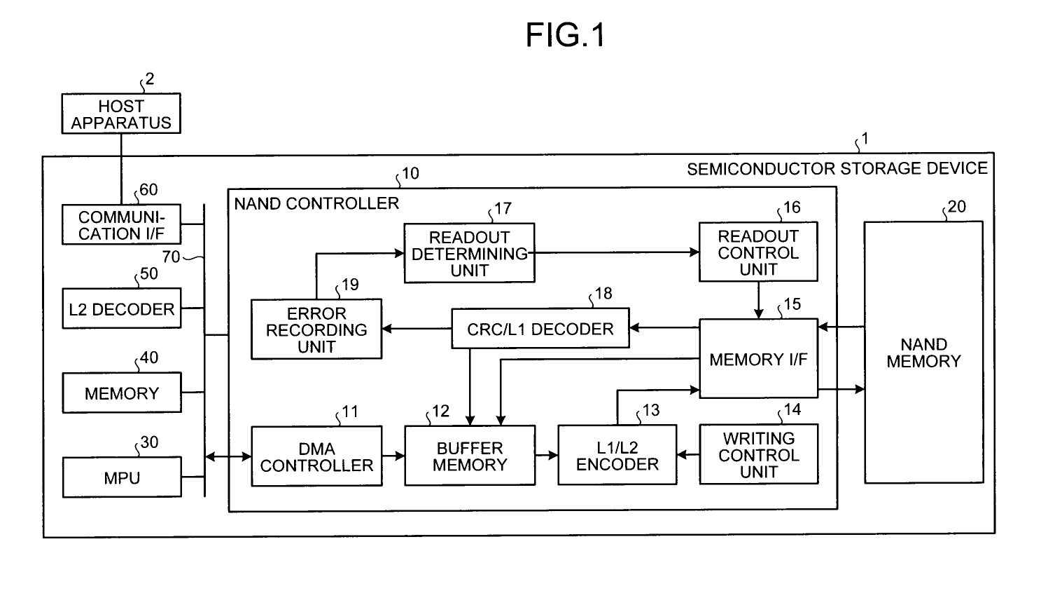

FIG. 1 is a diagram of a configuration example of a semiconductor storage device according to a first embodiment. A semiconductor storage device 1 according to this embodiment is a device for storing information in a nonvolatile manner using a semiconductor memory of, for example, solid state drive (SSD). The semiconductor storage device 1 is connected to the outside of a host apparatus 2 via a communication medium and functions as an external storage medium for the host apparatus 2. Examples of the host apparatus 2 include a personal computer and a central processing unit (CPU) core.

The semiconductor storage device 1 includes a NAND controller 10, a NAND flash memory (hereinafter abbreviated as “NAND memory”) 20, which is a nonvolatile semiconductor memory, a micro processing unit (MPU) 30, a memory 40 that can operate at higher speed than the NAND memory 20, an L2 decoder 50, a communication interface (I/F) 60, and an internal bus 70.

The NAND controller 10, the MPU 30, the memory 40, the L2 decoder 50, and the communication I/F 60 are connected to one another via the internal bus 70. An example in which a NAND flash memory is used as a semiconductor memory of the semiconductor storage device 1 is explained in this embodiment. However, the present invention is not limited to this. A nonvolatile semiconductor memory other than the NAND flash memory can also be used.

The communication I/F 60 is a memory connection interface such as an advanced technology attachment (ATA) interface. The communication I/F 60 outputs a command, data, and the like received from the host apparatus 2 to the internal bus 70. The communication I/F 60 transmits data input through the internal bus 70, response notification (e.g., notification indicating completion of execution of a command) from the MPU 30, and the like to the host apparatus 2.

The MPU 30 collectively controls the components of the semiconductor storage device 1. When the MPU 30 receives a command from the host apparatus 2 through the communication I/F 60 and the internal bus 70, the MPU 30 performs control conforming to the command. For example, the MPU 30 instructs, according to the command from the host apparatus 2, the NAND controller 10 to perform writing of data in the NAND memory 20, readout of data from the NAND memory 20, and the like.

The configuration of the semiconductor storage device 1 shown in FIG. 1 is an example. The configuration of the semiconductor storage device 1 is not limited to the configuration shown in FIG. 1. The semiconductor storage device 1 can have any configuration as long as the semiconductor storage device 1 includes a semiconductor memory and a controller for controlling reading and writing for the semiconductor memory and can communicate with the host apparatus 2.

The NAND controller 10 is a controller that controls reading, writing, and the like for the NAND memory 20. The NAND controller 10 includes a direct memory access (DMA) controller 11, a buffer memory 12, an L1/L2 encoder 13, a writing control unit 14, a memory I/F 15, a readout control unit 16, a readout determining unit 17, a cyclic redundancy check (CRC)/L1 decoder 18, and an error recording unit 19.

The DMA controller 11 performs data transfer control among the buffer memory 12, the L2 decoder 50, and the memory 40 according to a direct memory access (DMA) system. The buffer memory 12 functions as a temporary storage area at the time of data transfer from the DMA controller 11 to the L1/L2 encoder 13 and functions as a temporary storage area at the time when data read out from the NAND memory 20 is transferred to the DMA controller 11.

An operation for writing in the NAND memory 20 according to this embodiment is explained. Writing in and readout from the NAND memory 20 is performed in page units. A data amount of one page is not specifically limited. However, in the following explanation, as an example, one page has 8640 bytes.

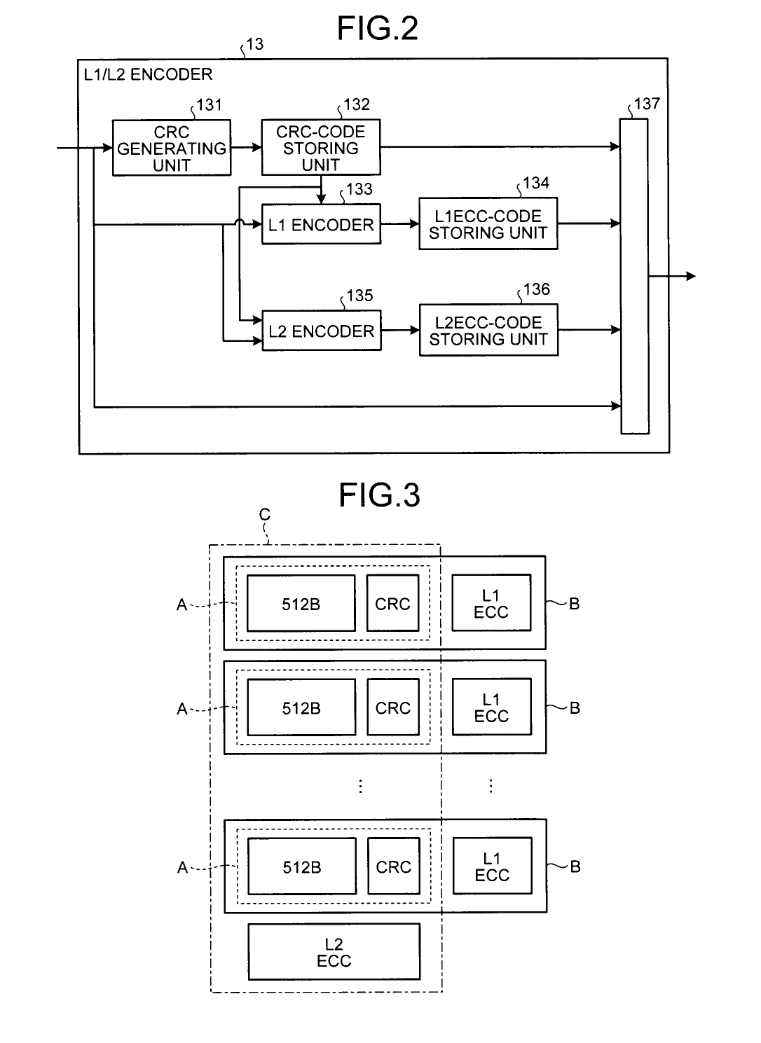

FIG. 2 is a diagram of a configuration example of the L1/L2 encoder 13 according to this embodiment. As shown in FIG. 2, the L1/L2 encoder 13 includes a cyclic redundancy check (CRC) generating unit (an error-detection-code generating unit) 131, a CRC-code storing unit 132, an L1 encoder 133, an L1ECC-code storing unit 134, an L2 encoder 135, an L2ECC-code storing unit 136, and a selecting unit 137.

In this embodiment, the L1/L2 encoder 13 performs ECC processing in two stages of a level 1 (L1) and a level 2 (L2). In L1ECC processing, the L1/L2 encoder 13 performs, for each write data having a predetermined size, processing for generating an error detection code for the write data and processing for generating an ECC code for applying error correction to the write data and the error detection code.

Specifically, first, the CRC generating unit 131 of the L1/L2 encoder 13 generates an error detection code based on write data having a predetermined size input from the buffer memory 12 and stores the generated error detection code in the CRC-code storing unit 132. As the error detection code used in the L1ECC processing, for example, a CRC 32 code, a CRC16 code, or the like can be used. In this embodiment, an example in which the CRC32 code is used as the error detection code used in the L1ECC processing is explained. The error detection code generated by the L1ECC processing is hereinafter referred to as CRC code.

The L1 encoder 133 generates an ECC code based on a CRC code read out from the CRC-code storing unit 132 and write data input from the buffer memory 12 and stores the generated ECC code in the L1ECC-code storing unit 134. The codes generated by the L1ECC processing are stored in the NAND memory 20 together with the write data. In this embodiment, a data unit including the codes (the error detection code and the ECC code) generated by the L1ECC processing and data corresponding to the codes (first encoding target data) is set as one sector (first unit data).

In the L2ECC processing, the L1/L2 encoder 13 generates, based on the write data and the CRC code corresponding to the write data, an ECC code different from the ECC code generated by the L1ECC processing. Specifically, the L2 encoder 135 generates an ECC code based on the write data having the predetermined size input from the buffer memory 12 and the CRC code read out from the CRC-code storing unit 132. In this embodiment, a data unit including data (second encoding target data: the write data and the CRC code) as a target of encoding of the L2ECC processing, the ECC code generated by the L1ECC processing corresponding to the data, and the ECC code generated by the L2ECC processing corresponding to the data is set as one cluster (second unit data).

As explained later, when data is read out from the NAND memory 20, presence or absence of an error is determined based on an error detection code in sector units. The error correction processing employing the ECC code in L1 is not carried out for data in a sector determined as not having an error. On the other hand, the error correction processing employing the ECC code in L1 is carried out for data in a sector determined as having an error. When there is no error in all sectors in a cluster or error correction by the ECC code in L1 is possible in all sectors in a cluster, the error correction processing in L2 is not carried out for the cluster. On the other hand, the error correction processing employing the ECC code in L2 is carried out for a cluster including a sector for which correction by the error correction processing employing the ECC code in L1 is impossible.

Therefore, the L1ECC processing is carried out for all the write data. The error correction code generated by the L1ECC processing (an L1ECC code) is desirably a code having small computational complexity. For example, a hamming code or the like can be used as the L1ECC code. Because the L2ECC processing is carried out when error correction cannot be performed by the L1ECC processing, an error correction code generated by the L2ECC processing (an L2ECC code) is desirably a code having large computational complexity but capable of correcting multi-bit error and a code having a higher error correction ability than the L1ECC code. For example, as the L2ECC code, a Bose Chaudhuri Hocquenghem (BCH) code, a Reed-Solomon (RS) code, or a low density parity check (LDPC) code, or the like can be used.

FIG. 3 is a diagram for explaining a concept of the ECC processing in two stages. In FIG. 3, error detection ranges A by the CRC, error correction ranges B by the L1ECC code, and an error correction range by the L2ECC code are shown. In an example shown in FIG. 3, the CRC code and the L1ECC code are generated for each writing target data of 512 bytes. The L2ECC code is generated for a plurality of 512 bytes data and CRC codes.

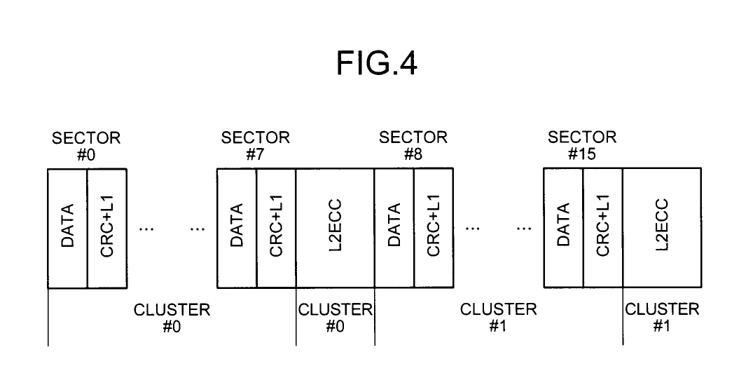

The CRC code, the L1ECC code, and the L2ECC code generated by the L1ECC processing and the L2ECC processing are written in the NAND memory 20 in page units. FIG. 4 is a diagram of an example of a page format according to this embodiment. The format shown in FIG. 4 is the same as a page format used by the semiconductor device in the past (the semiconductor device in the past that performs the ECC processing in two stages). The page format indicates order of writing and readout of data (including codes) in page units in writing and readout. The page format shown in FIG. 4 indicates that writing and readout are performed in order from the left side in the page format. In the example shown in FIG. 4, one page includes two clusters (a cluster #0 and a cluster #1). One cluster includes eight sectors (the cluster #0 includes sectors #0 to #7 and the cluster #1 includes sectors #8 to #15) and the L2ECC code. One sector includes write data and a CRC code corresponding to the write data.

The selecting unit 137 outputs, based on an instruction from the writing control unit 14, any one of the CRC code read out from the CRC-code storing unit 132, the L1ECC code read out from the L1ECC-code storing unit 134, the L2ECC code read out from the L2ECC-code storing unit 136, and the write data input from the buffer memory 12 to the memory I/F 15 such that the page format explained above is obtained. In this way, the write data and the codes output from the selecting unit 137 are written in the NAND memory 20 through the memory I/F 15.

An operation for writing in the NAND memory 20 and a configuration related the writing operation (the configuration of the L1/L2 encoder) are the same as those of the semiconductor storage device in the past that performs the ECC processing in two stages and are not limited to the operation and the configuration explained above. Any operation and configuration can be used as long as the error correction code, the L1ECC code, and the L2ECC code can be generated and writing can be performed in page units.

An operation for reading out data from the NAND memory 20 according to this embodiment is explained. When a readout instruction is received from the MPU 30, the readout control unit 16 instructs the memory I/F 15 to read out readout data and the codes generated in the writing processing from the NAND memory 20. The readout control unit 16 usually instructs the memory I/F 15 to collectively read out, for each of pages, the start of the page to the end of the page. However, it is also possible to instruct the memory I/F 15 to read out from the middle of the page (an instruction of a readout start position) and instruct the memory I/F 15 to readout the page to the middle of the page (an instruction of a readout end position).

The memory I/F 15 has a function of a readout processing unit for readout from the NAND memory 20. The memory I/F 15 stores readout data read out from the NAND memory 20 in the buffer memory 12 and inputs read out data read out from the NAND memory 20 for each of sectors and the CRC code and the L1ECC code corresponding to the readout data to the CRC/L1 decoder 18. The memory I/F 15 has a function of a writing processing unit for writing in the NAND memory 20. The memory I/F 15 writes, based on an instruction from the writing control unit 14, data output from the L1/L2 encoder 13 in the NAND memory 20. The readout control unit 16 stores the read-out L2ECC code.

The CRC/L1 decoder 18 performs L2 decode processing based on the input L1ECC code and readout data to thereby generate readout data and a CRC code after error correction. When the CRC/L1 decoder 18 determines, based on the readout data and the CRC code after error correction, that there is an error in the readout data, the CRC/L1 decoder 18 records information indicating that the error occurs in a relevant cluster in the error recording unit 19 and stores the readout data and the CRC code (before error correction by the L1ECC code), which are stored in the buffer memory 12, in the DMA memory 40 through the DMA controller 11.

When the CRC/L1 decoder 18 determines, based on the readout data and the CRC code after error correction, that there is no error in the readout data, the CRC/L1 decoder 18 rewrites the readout data stored in the buffer memory 12 with data after error correction and stores the data in the DMA memory 40 through the DMA controller 11.

The CRC/L1 decoder 18 performs, based on the readout data and the CRC code after error correction, determination concerning whether there is an error in the readout data (correction by the L1 error correction code is possible), for example, according to a procedure explained below. First, the CRC/L1 decoder 18 performs syndrome calculation. Subsequently, when there are errors as a result of the syndrome calculation, the CRC/L1 decoder 18 calculates error positions and performs Chien search. The number of errors is found by the calculation of error positions. The CRC/L1 decoder 18 checks the positions of the errors and the number of errors while carrying out the Chien search. When the correction by the L1ECC code is impossible, the number of errors checked by the Chien search and the number of errors calculated by the calculation of error positions are different values. Therefore, when the number of errors checked by the Chien search and the number of errors calculated by the calculation of error positions are different, the CRC/L1 decoder 18 can determine that the error correction by L1ECC code is impossible.

When the error correction by the L1ECC code is possible, the number of errors checked by the Chien search and the number of errors calculated by the calculation of error positions coincide with each other. However, even if the numbers of errors coincide with each other, it is likely that errors are corrected by mistake. Therefore, finally, the CRC/L1 decoder 18 performs error correction based on the readout data and the CRC code. When there is no error, the CRC/L1 decoder 18 determines that the error correction by the L1ECC code is possible. When there is an error, the CRC/L1 decoder 18 determines that the error correction by the L1ECC code is impossible.

The readout determining unit 17 determines, based on error information stored in the error recording unit 19, for example, whether normal readout is continued or a readout end position of a page being read out is changed. The readout determining unit 17 notifies the MPU 30, based on the error information stored in the error recording unit 19, whether the error correction by the L1ECC code is impossible (an error remains after the L1 error correction). The MPU 30 acquires, based on the notification, the L2ECC code from the readout control unit 16 for a cluster for which the L1 correction is determined as impossible. The MPU 30 passes the acquired L2ECC code to the L2 decoder 50 and instructs the L2 decoder 50 to start error correction processing by the L2ECC code for the cluster.

The L2 decoder 50 performs, according to the instruction from the MPU 30 and based on the readout data and the CRC code stored in the memory 40, error correction processing for the readout data and the CRC code and rewrites the readout data with data after error correction.

The processing by the readout determining unit 17 is explained in detail. In the semiconductor storage device in the past that performs the ECC processing in two stages, the L2ECC code is read out from the NAND memory 20 even for a cluster for which the error correction processing employing the L2ECC code (the L2 error correction processing) is not carried out. Therefore, readout speed due to readout of unnecessary information from the NAND memory 20 occurs. In this embodiment, as measures against such a problem, the NAND controller 10 includes the readout determining unit 17 that determines whether the L2ECC code is read out. When the readout determining unit 17 determines that the L2ECC code is not read out, the L2ECC code is not read out from the NAND memory 20.

In this embodiment, it is assumed that the page format shown in FIG. 4 is used. As shown in FIG. 4, the L2ECC code is stored in the last section of each of the clusters. For example, when there is no error remaining after the error correction processing employing the L1ECC code in all the sectors #8 to #15 of the cluster #1, it is unnecessary to read out the L2ECC code of the cluster #1. In this case, during readout of a relevant page, if an end position of readout from the NAND memory 20 is changed to an end position of the sector #15, the L2ECC code is not read out.

Concerning the cluster #0, similarly, when an error is not detected or when correction can be performed by using the L1ECC code in all the sectors #0 to #7, it is unnecessary to read out the L2ECC code of the cluster #0. In this case, not to read out the L2ECC code of the cluster #0, it is necessary to, during read out of the page, once change an end position of readout from the NAND memory 20 to an end position of the sector #7 and, thereafter, start readout from a start position of the sector #8 of the cluster #1. When such readout control processing can be carried out in short time compared with time for reading the L2ECC code, reading of the L2ECC code can be skipped for the cluster #0 and the cluster #1. On the other hand, when such readout control processing is carried out in time equal to or longer than the time for reading out the L2ECC code, reading of the L2ECC code is not skipped for the cluster #0 and the L2ECC code is read out.

For example, one sector is set to 520 bytes, one cluster is set to 4320 bytes, the L2ECC code is set to 160 bytes, and a required time for reading out the L2ECC code from the NAND memory 20 is set to 320 clocks (1 byte is read out in 2 clocks). The readout end position is changed to an end position of the sector #7. Thereafter, a required time (including a standby time) of the readout control processing for starting readout from a start position of the sector #8 of the cluster #1 is set to about 30 cycles. In this case, the required time of the readout control processing is shorter than the required time of readout. Therefore, reading of the L2ECC code of the cluster #0 can also be skipped. Even when the required time of the readout control processing is short compared with the required time of readout, reading of only the L2ECC code of the cluster #1 can be skipped taking into account the fact that, for example, the readout control processing for the cluster #0 is complicated.

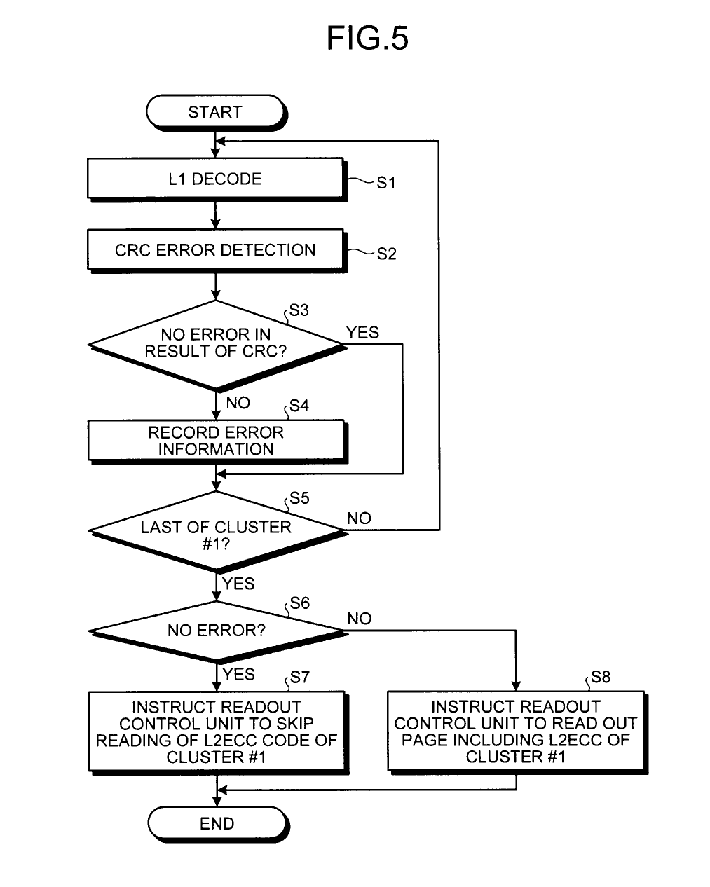

FIG. 5 is a flowchart for explaining an example of a procedure of L2ECC code readout determination processing according to this embodiment. In FIG. 5, readout processing is performed only for the L2ECC code of the cluster #1. When L2ECC code readout determination processing is performed for the cluster #0, the same operation only has to be performed with the cluster #1 in FIG. 5 read as the cluster #0 (at step S7 explained later, when the L2ECC code of the cluster #0 is not read out, a readout end position is an end position of the sector #7).

First, the CRC/L1 decoder 18 performs L1 decode processing based on readout data, the CRC code, and the L1ECC code and carries out error correction for the readout data and the CRC code (step S1). Thereafter, the CRC/L1 decoder 18 carries out error detection processing for the readout data (determination processing using the CRC) based on the readout data and the CRC code after the error correction (step S2). The CRC/L1 decoder 18 determines whether there is an error in the readout data as a result of the determination of the CRC (step S3). When the CRC/L1 decoder 18 determines that there is an error (“No” at step S3), the CRC/L1 decoder 18 records information for identifying a cluster to which a sector in which the error is detected belongs and error information indicating whether there is an error in association with each other (step S4).

When the CRC/L1 decoder 18 determines at step S3 that there is no error (“Yes” at step S3), the CRC/L1 decoder 18 determines whether the sector for which the determination processing is performed at step S2 is a last sector of the cluster #1 (step S5). When the CRC/L1 decoder 18 determines that the sector is not the last sector of the cluster #1 (“No” at step S5), the CRC/L1 decoder 18 returns to step S1 and carries out the processing for the next sector. When the CRC/L1 decoder 18 determines at step S5 that the sector is the last sector of the cluster #1 (“Yes” at step S5), the CRC/L1 decoder 18 instructs the readout determining unit 17 to carry out determination processing. The readout determining unit 17 determines, referring to the error information stored in the error recording unit 19, whether there is no error in all the sectors in the cluster #1 (step S6).

When the readout determining unit 17 determines that there is no error in all the sectors in the cluster #1 (“Yes” at step S6), the readout determining unit 17 instructs the readout control unit 16 not to read out the L2ECC code of the cluster #1 (to set an end position of the sector #15 as a readout end position) (step S7). The readout control unit 16 controls, based on the instruction from the readout determining unit 17, readout from the NAND memory 20 to set the end position of the sector #15 of the cluster #1 as the readout end position.

When the readout determining unit 17 determines at step S6 that there is at least one error in the sectors in the cluster #1 (“No” at step S6), the readout determining unit 17 does not issue an additional instruction concerning readout and continues normal readout (step S8). Specifically, the readout determining unit 17 reads out the L2ECC code of the cluster #1 from the NAND memory 20. According to the processing explained above, when there is no error after correction by the L1ECC code in all the sectors in the cluster #1, the readout determining unit 17 can be configured not to read out the L2ECC code from the NAND memory 20.

For example, one sector is set to 520 bytes, one cluster is set to 4320 bytes, and the L2ECC code is set to 160 bytes. In this case, one page has 8640 bytes. When the entire one page is read out, 8640 bytes are read out. On the other hand, when the L2ECC code of the cluster #1 is not read out, 8480 bytes (8640 bytes−160 bytes) is read out. Compared with the readout of the entire page, readout speed can be improved by about 1.8%.

When the L2ECC code of the cluster #0 is not read out either, the readout speed can be further improved by time obtained by deducing time for the readout control processing (processing for once ending readout and then resuming the readout) from the readout time for 160 bytes. Specifically, when time for reading out 1 byte is set to 1 cycle and the readout time is set to T cycles, compared with the normal readout, the readout speed can be improved by (160+160-T)/8640×100%. For example, when T is set to 30 cycles, the readout speed can be improved by about 3.4%. For example, when T exceeds 160 cycles, speed improvement by not reading out the L2ECC code of the cluster #0 cannot be expected. Therefore, the readout determination processing has to be carried out only for the L2ECC code of the cluster #1.

A readout operation and a configuration related to the readout operation according to this embodiment other than the readout determining unit 17 are the same as those of the semiconductor storage device in the past that performs the ECC processing in two stages and are not limited to the operation and the configuration explained above. Any operation and configuration can be used as long as error detection based on an error detection code and error correction based on the L1ECC code and the L2ECC code can be carried out and readout can be performed in page units.

In this embodiment, the example in which readout is performed in page units is explained. However, the present invention is not limited to this. For example, even if a unit of one readout is undefined, the L2ECC readout determination processing can be performed in the same manner. For example, when a unit of one readout is undefined, the readout determination processing only has to be performed for each of the clusters to determine whether the L2ECC code is read out.

In this embodiment, when it is determined after the L1ECC processing that there is no error, i.e., when it is unnecessary to perform the L2ECC processing, the readout determining unit 17 does not read out the L2ECC code. Further, it is also possible that, when the CRC/L1 decoder 18 determines before the error correction processing employing the L1ECC code that there is no error using the CRC code, the readout determining unit 17 does not read out the L1ECC code of a relevant sector. In that case, a page format for reading out the CRC code earlier than the L1ECC code for one sector is adopted.

In this embodiment, the example in which the ECC processing in two stages is performed is explained. However, an operation same as the operation in this embodiment can be applied when error detection processing and ECC processing in one stage (error correction processing employing an ECC code in one stage) are performed with the CRC code. In this case, the readout determining unit 17 does not read out the ECC code in one stage for data determined by the error detecting unit, which performs error detection with the CRC code, as not having an error.

As explained above, in this embodiment, when there is no error or correction by the L1ECC code can be performed in all sectors included in a cluster, the readout determining unit 17 does not read out the L2ECC code of the cluster. Therefore, it is possible to improve readout speed compared with the semiconductor storage device in the past that performs the ECC processing in two stages.

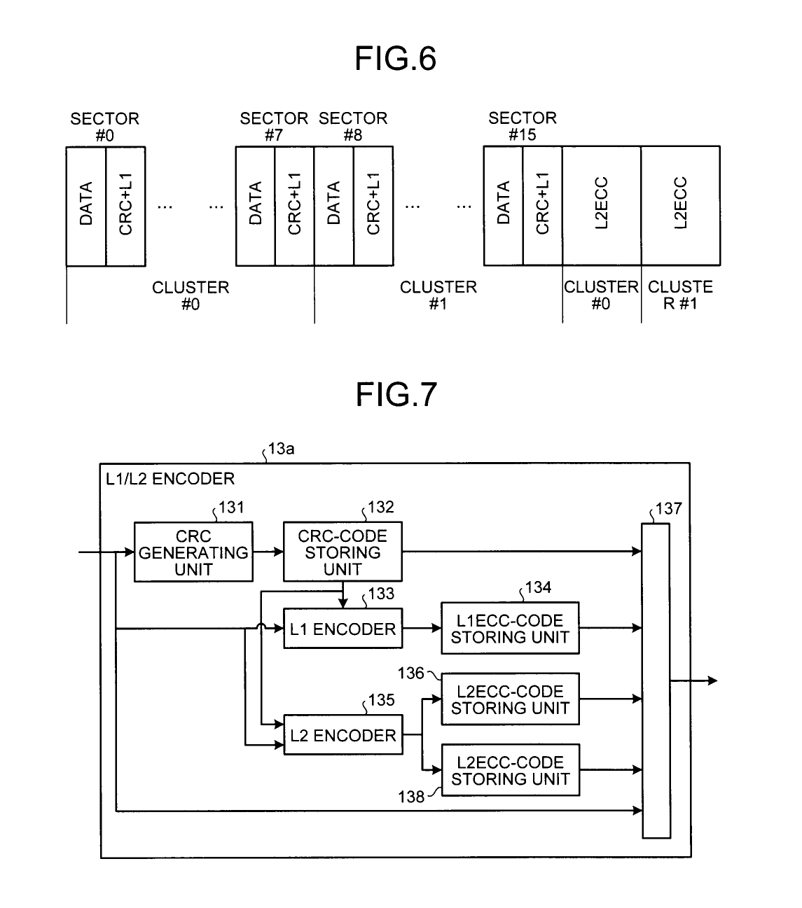

FIG. 6 is a diagram of an example of a page format used by a semiconductor storage device according to a second embodiment. FIG. 7 is a diagram of a configuration example of an L1/L2 encoder 13a according to this embodiment. The configuration of the semiconductor storage device according to this embodiment is the same as the configuration of the semiconductor storage device 1 according to the first embodiment except that the L1/L2 encoder 13 of the semiconductor storage device 1 according to the first embodiment is replaced with an L1/L2 encoder 13a according to this embodiment. Components having functions same as those in the first embodiment are denoted by reference numerals and signs same as those in the first embodiment and explanation of the components is omitted. Differences from the first embodiment are explained below.

As shown in FIG. 6, in this embodiment, the L2ECC code of the cluster #0 is arranged immediately before the L2ECC code of the cluster #1 such that the L2ECC codes are continuously arranged at the end of each of pages. To correspond to such a page format, in the L1/L2 encoder 13a according to this embodiment, an L2ECC-code storing unit 138 is added to the L1/L2 encoder 13 according to the first embodiment.

In this embodiment, the L2 encoder 135 stores the generated L2ECC code of the cluster #0 in the L2ECC-code storing unit 136 and stores the generated L2ECC code of the cluster #1 in the L2ECC-code storing unit 138. The selecting unit 137 outputs, based on an instruction from the writing control unit 14, any one of the CRC code read out from the CRC-code storing unit 132, the L1ECC code read out from the L1ECC-code storing unit 134, the L2ECC code read out from the L2ECC-code storing unit 136, the L2ECC code read out from the L2ECC-code storing unit 138, and the write data input from the buffer memory 12 to the memory I/F 15 such that the page format shown in FIG. 6 is obtained.

As shown in FIG. 6, the L2ECC codes are continuously arranged at the end of each of the pages. This makes it possible to efficiently perform skip of reading when the L2ECC codes are not read out in both the cluster #0 and the cluster #1. Specifically, when there is no error or when correction can be performed by the L1ECC code in all the sectors in both the cluster #0 and the cluster #1, a readout end position is set in an end position of the cluster #15. This makes it possible not to read out both the L2ECC codes only by changing an end position once.

In the case of the page format according to the first embodiment, when the L2ECC codes are not read out in both the cluster #0 and the cluster #1, concerning the cluster #0, it is necessary to once change a readout end position and then start readout from the middle. Processing for the readout control requires a certain degree of time. On the other hand, in this embodiment, when the L2ECC codes are not read out in both the cluster #0 and the cluster #1, the read out end position only has to be set in the end position of the cluster #15.

When the L2ECC code of the cluster #0 is not read out and the L2ECC code of the cluster #1 is read out, after the readout end position is changed to the end position of the cluster #15, readout is performed from a start position of the L2ECC code of the cluster #1. When the L2ECC code of the cluster #0 is read out and the L2ECC code of the cluster #1 is not read out, the readout end position is changed to an end position of the L2ECC code of the cluster #0.

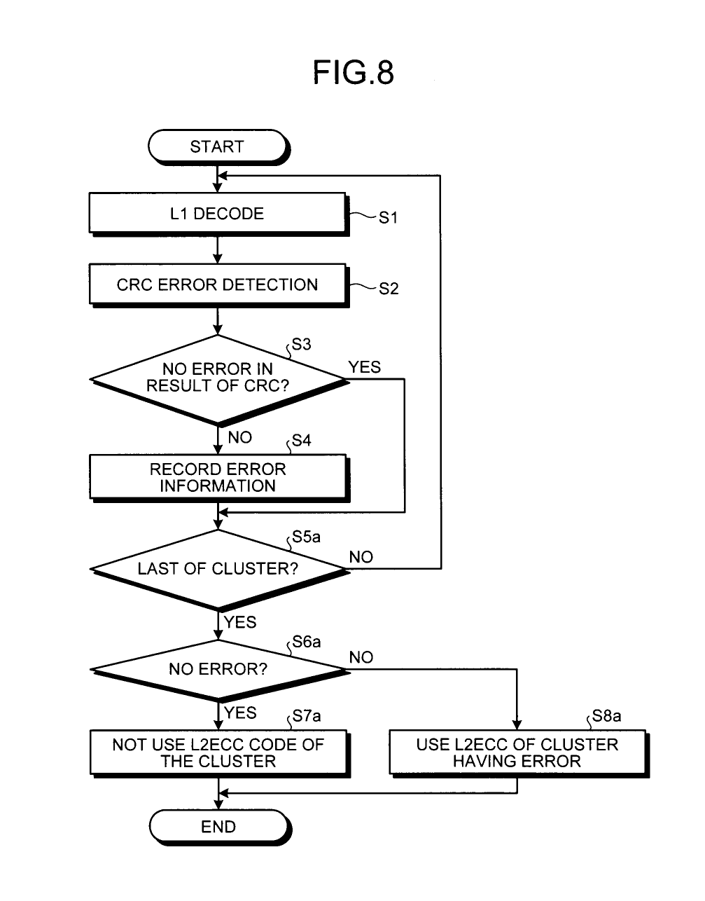

FIG. 8 is a flowchart for explaining an example of a procedure of processing for determining use/nonuse of the L2ECC code according to this embodiment carried out for each of the clusters. In this embodiment, first, the CRC/L1 decoder 18 and the readout determining unit 17 perform, for each of the clusters, determination of use/nonuse of the L2ECC code according to the procedure shown in FIG. 8. Steps S1, S2, S3, and S4 of the flowchart shown in FIG. 8 are the same as the corresponding steps of the flowchart shown in FIG. 5. Differences from the readout determination processing procedure according to the first embodiment are explained below.

In this embodiment, when the CRC/L1 decoder 18 determines at step S3 that there is no error as a result of the determination of the CRC (“Yes” at step S3), the CRC/L1 decoder 18 determines whether the determination result is a determination result of a last sector of a cluster being read out (step S5a). When the determination result is the determination result of the last sector of the cluster being read out (“Yes” at step S5a), the CRC/L1 decoder 18 instructs the readout determining unit 17 to carry out readout determination processing and proceeds to step S6a. When the determination result is not the determination result of the last sector of the cluster being read out (“No” at step S5a), the CRC/L1 decoder 18 returns to step S1.

At step S6a, the readout determining unit 17 determines whether there is no error in the cluster being read out (step S6a). When the readout determining unit 17 determines that there is no error (“Yes” at step S6a), the readout determining unit 17 determines that the L2ECC code of the cluster is not use and stores a result of the determination as a code use determination result together with an identification number of the cluster (step S7a). When the readout determining unit 17 determines at step S6a that there is an error in the cluster being read out (“No” at step S6a), the readout determining unit 17 determines that the L2ECC code of the cluster is used and stores a result of the determination as a code use determination result together with the identification number of the cluster (step S8a).

After obtaining the code use determination results respectively for the clusters #0 and #1, the readout determining unit 17 gives, based on the code use determination result for each of the clusters, an instruction to the readout control unit 16. Specifically, when the code use determination results indicate that the L2ECC codes of both the clusters #0 and #1 are used, the readout determining unit 17 continues the normal readout. When the code use determination results indicate that the L2ECC code of the cluster #0 is used and the L2ECC code of the cluster #1 is not used, the readout determining unit 17 instructs the readout control unit 16 to set the readout end position in an end position of the L2ECC code of the cluster #0. When the code use determination results indicate that the L2ECC code of the cluster #0 is not used and the L2ECC code of the cluster #1 is used, the readout determining unit 17 starts, after setting the readout end position in an end position of the sector #15 of the cluster #0, readout from the top of the L2ECC code of the cluster #1. When the code use determination results indicate that the L2ECC codes of both the cluster #0 and the cluster #1 are not used, the readout determining unit 17 instructs the readout control unit 16 to set the readout end position in the end position of the cluster #15.

For example, one sector is set to 520 bytes, one cluster is set to 4320 bytes, and the L2ECC code is set to 160 bytes. In this case, in this embodiment, when the L2ECC codes of both the cluster #0 and the cluster #1 are not read out, 8320 bytes (8640 bytes−160 bytes−160 bytes) is read out. Compared with the readout of the entire page, readout speed can be improved by about 3.8%.

When the code use determination results indicate that the L2ECC of the cluster #0 is not used and the L2ECC code of the cluster #1 is used, the readout determining unit 17 can also continue the normal readout. This is because, since it is necessary to perform processing for once changing a readout position and starting readout again, a certain degree of required time is necessary for the processing. For example, when the required time for the processing is equal to or longer than readout time for the cluster #0, the readout determining unit 17 can also continue the normal readout. The operation in this embodiment explained above is the same as the operation in the first embodiment.

As explained above, in this embodiment, the L2ECC codes of the cluster #0 and the cluster #1 are continuously arranged at the end of one page. When there is no error or when correction by the L1ECC code can be performed in all the sectors included in both the cluster #0 and the cluster #1, reading of the L2ECC can be continuously skipped. Therefore, compared with the first embodiment, the readout speed can be further improved.

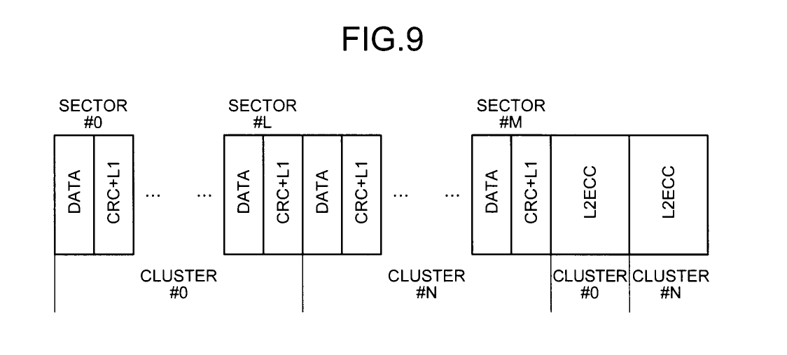

FIG. 9 is a diagram of an example of a page format used by a semiconductor storage device according to a third embodiment. The configuration of the semiconductor storage device according to this embodiment is the same as that in the first embodiment except that the L1/L2 encoder 13 of the semiconductor storage device according to the first embodiment is configured to be capable of storing the L2ECC codes for N+1 clusters (N is an integer equal to or lager than 1). Components having functions same as those in the first embodiment are denoted by reference numerals and signs same as those in the first embodiment and explanation of the components is omitted. Differences from the first or second embodiment are explained below.

In this embodiment, one page includes N+1 clusters. As in the second embodiment, the L2ECC codes of clusters in a page are continuously arranged at the end of the page. In FIG. 9, M+1 sectors #0 to #M (M is an integer equal to or larger than 1) are included in one page. In this embodiment, one cluster includes L+1 sectors (L is an integer equal to or lager than 1). In the first and second embodiments, the example in which one page has 8640 bytes, one page includes two clusters, and one cluster includes eight sectors is explained. On the other hand, in future, page length is considered to increase and a larger error correction ability is considered to be required. It is likely that the number of bits of the L2ECC code also increases. Therefore, in this embodiment, an example in which page length, the number of clusters in one page, and the number of sectors in one cluster are generalized is explained.

In this embodiment, the readout determining unit 17 carries out, as readout determination processing, for each of the clusters, the processing for determining use/nonuse of the L2ECC code (the processing procedure shown in FIG. 8) explained in the second embodiment. The readout determining unit 17 determines an instruction to the readout control unit 16 based on code use determination results concerning the clusters included in one page. For example, when the code use determination results indicate that the L2ECC codes are not used in all the cluster of the page being read out, the readout determining unit 17 instructs the readout control unit 16 to set the readout end position immediately before a storage position of the continuous L2ECC codes (an end position of the sector #M). When the code use determination results indicates that the L2ECC codes are used in all the clusters of the page being read out, the readout determining unit 17 continues the normal readout.

When the code use determination results indicate that the L2ECC codes are not used in K clusters (K is an integer satisfying a condition 1≦K≦N) and the L2ECC codes are used in the remaining (N+1)−K clusters, the readout determining unit 17 does not have to read out all the L2ECC codes determined as not to be used. The readout determining unit 17 can also determine, based on, for example, positions of the L2ECC codes not to be used, whether the L2ECC codes are read out. It is also possible that, for example, when K is 1, when the L2ECC code is the last L2ECC code on the page format, the readout determining unit 17 does not read out the L2ECC and, when the L2ECC code is not the last L2ECC code on the page format, the readout determining unit 17 continues the normal readout. It is also possible that, when K is 2, when the L2ECC codes not to be read out continue on the page format, the readout determining unit 17 does not read out the L2ECC codes and, when the L2ECC codes not to be read out do not continue (locate separate positions), the readout determining unit 17 continues the normal read out. The operation in this embodiment explained above is the same as the operation in the second embodiment.

For example, page length is set to 10000 bytes and a total of the L2ECC codes for all the clusters in one page is set to 100 bytes. When not all the L2ECC codes are read out, readout speed can be improved by about 10% compared with readout speed in reading out all the L2ECC codes.

In this embodiment, as in the second embodiment, the L2ECC codes are continuously arranged at the end of the page. However, as in the first embodiment, the L2ECC code can also be arranged for each of the clusters. In that case, as in the first embodiment, the readout determining unit 17 can also determine whether readout of the L2ECC code is performed in a last cluster of each of the pages and read out the L2ECC codes of the other clusters. The readout determining unit 17 can also determine whether readout of the L2ECC code is performed for each of the clusters.

For example, when N is equal to or larger than 3, the L2ECC codes can also be arranged for every two clusters. For example, the L2ECC codes of the cluster #0 and the cluster #1 are continuously arranged after the readout data, the CRC codes, and the L2ECC codes of the cluster #0 and the cluster #1 and the L2ECC codes of the cluster #2 and the cluster #3 are continuously arranged after the readout data, the CRC codes, and the L2ECC codes of the cluster #2 and the cluster #3. It is also possible that the clusters in the page are divided into two, i.e., clusters in the former half and clusters in the latter half and the L2ECC codes are continuously arranged at the ends of the former half and the latter half. As in these examples, a page format for arranging the L2ECC codes in two or more places such that the two or more L2ECC codes continues can also be adopted.

As explained above, in this embodiment, when the number of clusters included in a page is arbitrary and the number of sectors included in a cluster is arbitrary, the L2ECC codes are continuously arranged at the end of the page. When there is no error or error correction by the L1ECC code can be performed in all the sectors of all the clusters included in one page, reading of the L2ECC codes can be continuously skipped. Therefore, it is possible to improve the readout speed compared with that in the past irrespective of the number of clusters included in the page. As the number of bits of the L2ECC code is larger and the number of clusters included in the page is larger, the effect of the improvement of the readout speed is higher.

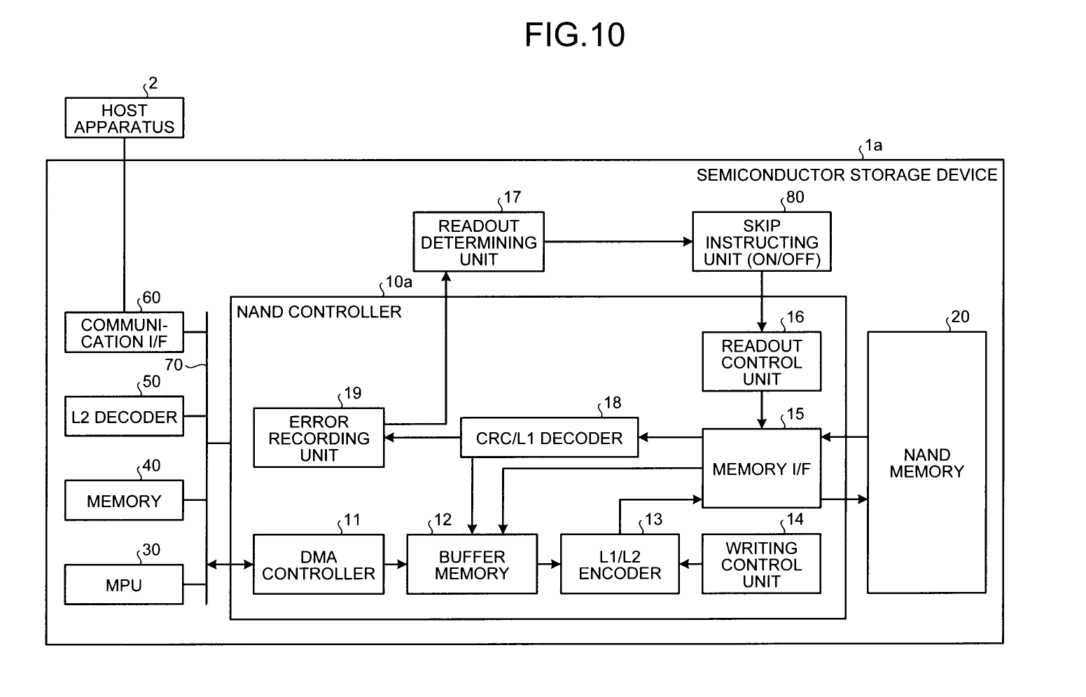

FIG. 10 is a diagram of a configuration example of a semiconductor storage device according to a fourth embodiment. A semiconductor storage device la according to this embodiment is the same as the semiconductor storage device 1 according to the first embodiment except that the NAND controller 10 of the semiconductor storage device 1 according to the first embodiment is replaced with a NAND controller 10a, a skip instructing unit 80 is added, and the readout determining unit 17 is provided on the outside of the NAND controller 10a. Components having functions same as those in the first embodiment are denoted by reference numerals and signs same as those in the first embodiment and explanation of the components is omitted.

In this embodiment, the readout determining unit 17 provided on the inside of the NAND controller 10 in the first embodiment is provided on the outside of the NAND controller 10a. The NAND controller 10a is the same as the NAND controller 10 according to the first embodiment except that the readout determining unit 17 is removed.

In this embodiment, a situation in which an error after error correction by the L1ECC code hardly occurs is assumed. In an initial state, the L2ECC codes are set always not to be read out in all clusters. The skip instructing unit 80 instructs the readout control unit 16, based on a determination result of the readout determining unit 17, whether skip of reading of the L2ECC code is performed (on or off). As explained above, in the initial state, the skip instructing unit 80 sets skip processing to on (the L2ECC code is not read out).

The page format explained in the second embodiment is the premise of this embodiment. In the initial state, the L2ECC codes are set not to be read out in both the cluster #0 and the cluster #1.

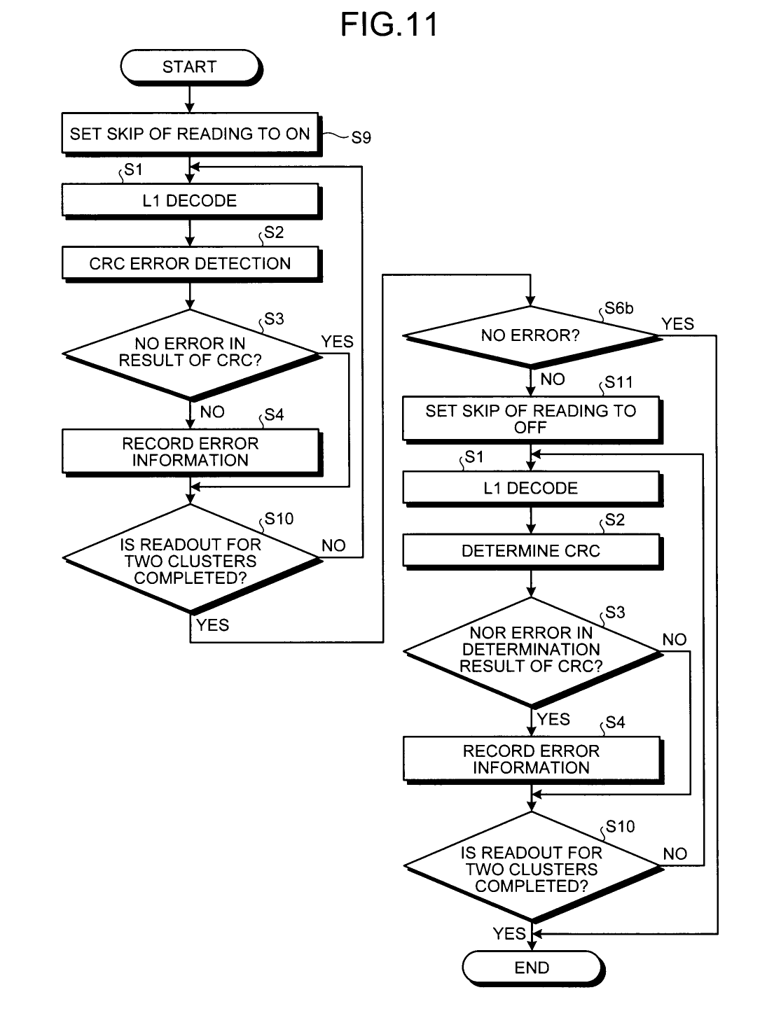

FIG. 11 is a flowchart for explaining an example of a procedure of readout determination processing according to this embodiment. First, the skip instructing unit 80 sets skip of reading to on in the initial state and instructs the readout control unit 16 not to read out the L2ECC code (step S9). Subsequently, steps S1 to S4 are carried out in the same manner as the processing explained with reference to FIG. 5 in the first embodiment. When the CRC/L1 decoder 18 determines at step S3 that there is no error (“Yes” at step S3), the CRC/L1 decoder 18 determines whether readout for one page (in this case, readout for two clusters) ends (step S10). When the readout for one page does not end (“No” at step S10), the CRC/L1 returns to step S1.

When the readout for one page ends (“Yes” at step S10), the CRC/L1 decoder 18 notifies the readout determining unit 17 of identification information of the page for which the readout ends. The readout determining unit 17 determines, referring to error information stored in the error recording unit 19 corresponding to the notified page, whether there is no error in clusters in the page (step S6b).

When there is no error in the clusters in the page (“Yes” at step S6b), the readout determining unit 17 ends readout determination processing for the page. When there is an error in the clusters in the page (“No” at step S6b), the readout determining unit 17 instructs the skip instructing unit 80 to set skip of reading of the L2ECC code to off (step S11). The skip instructing unit 80 sets the skip of reading of the L2ECC code to off and instructs the readout control unit 16 to read out the page including the L2ECC code (perform re-readout). Thereafter, the memory I/F 15 starts, based on an instruction of the readout control unit 16, readout of the page including the L2ECC code and carries out steps S1 to S4 and step S10 for read-out data. However, at step S10 (step S10 after the re-readout), when the CRC/L1 decoder 18 determines that the readout for one page is completed (“Yes” at step S10), the CRC/L1 decoder 18 ends the readout processing. Operations in this embodiment other than the operation explained above are the same as those in the second embodiment.

When the re-readout is performed, the data after being processed by the CRC/L1 decoder 18 is transferred from the buffer memory 12 to the memory 40 in the same manner as in the first embodiment. The L2 decoder 50 carries out error correction processing employing the L2ECC code.

The skip instructing unit 80 returns to the initial state in every readout of a page and sets the skip to on. According to the processing, when the skip instructing unit 80 receives an instruction for setting the skip to off from the readout determining unit 17, the skip instructing unit 80 sets the skip to off. By repeating such operations, it is possible not to read out the L2ECC code in a page in which there is no error in a result of the error correction processing employing the L1ECC code and to read out the L2ECC code through re-readout in a page in which there is an error in a result of the error correction processing employing the L1ECC code.

In this embodiment, to make the processing after readout from the NAND memory 20 common in the readout in the initial state (the readout for setting the skip of reading of the L2ECC code to on) and the re-readout performed after the skip is set to off, steps S1 to S4 and step S10 are carried out in the case of the re-readout. However, the present invention is not limited to this. It is also possible that, in the re-readout, the processing by the CRC/L1 decoder 18 is omitted, the re-readout data written in the buffer memory 12 through the memory I/F 15 is transferred to the memory 40, and the L2 decoder 50 performs the L2ECC processing.

In the case of the page format explained in the first embodiment, the operation in this embodiment is also applicable. When the page format explained in the first embodiment is used, the L2ECC code is not read out in the cluster #1 in the initial setting. However, concerning the L2ECC code of the cluster #0, it is set whether the L2ECC code is read out according to a relation between the required time of the readout control processing and the readout time of the L2ECC code as explained above. The operation in this embodiment is also applicable when the number of clusters in a page is generalized as explained in the third embodiment. In this case, at step S10, the CRC/L1 decoder 18 determines whether N+1 clusters for one page are read out.

As explained above, in this embodiment, the L2ECC code is not read out in the initial state. A page in which an error is detected after the error correction by the L1ECC code is read out again together with the L2ECC code. Therefore, it is unnecessary to carry out the determination processing of the readout determining unit 17 (step S6b) while one page is being read out. This makes it possible to simply the processing.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor storage device comprising:
a nonvolatile semiconductor memory;
a writing processing unit that writes, in the nonvolatile semiconductor memory, write data having a predetermined size, an error detection code generated to detect an error in the write data, a first error correction code generated to correct an error in first encoding target data including the write data and the error detection code corresponding to the write data, and a second error correction code generated to correct an error in a second encoding target data including a singularity or a plurality of the first encoding target data;
a first error correction processing unit that carries out first error correction processing for the write data using the write data, the error detection code, and the first error correction code read out from the nonvolatile semiconductor memory and determines whether there is an error remaining in the write data after the first error correction processing;
a second error correction processing unit that carries out second error correction processing for the write data using the second encoding target data including the write data determined as having the remaining error by the first error correction processing unit and the second error correction code read out from the nonvolatile semiconductor memory;
a readout determining unit that determines, based on a determination result by the first error correction processing unit for the write data in the second encoding target data, whether the second error correction code corresponding to the second encoding target data is read out from the nonvolatile semiconductor memory; and
a readout control unit that controls, based on a result of the determination by the readout determining unit, readout from the nonvolatile semiconductor memory.

2. The semiconductor storage device according to claim 1, wherein,
first unit data includes the first encoding target data and the first error correction code corresponding to the first encoding target data, second unit data includes the second encoding target data, the first error correction code corresponding to the first encoding target data included in the second encoding target data, and the second error correction code corresponding to the second encoding target data, and readout unit data includes a singularity or a plurality of the second unit data,
the semiconductor storage device further comprises a writing control unit that performs, for each of the readout unit data, control based on predetermined order such that second encoding target data, the first error correction code corresponding to the first encoding target data included in the second encoding target data, and the second error correction code corresponding to the second encoding target data are written in the nonvolatile semiconductor memory,
the readout control unit controls, for each of the readout unit data, readout from the nonvolatile semiconductor memory based on the predetermined order, and
the first error correction processing unit performs, for each of the first unit data, the first error correction processing and determination concerning whether there is an error remaining in the write data.

3. The semiconductor storage device according to claim 2, wherein the predetermined order is order in which, for each of the second unit data, the first unit data in the second unit data and the first error correction code corresponding to the first unit data are continuously read out and readout of the second error correction code is immediately after readout of the second encoding target data corresponding to the second error correction code.

4. The semiconductor storage device according to claim 2, wherein the predetermined order is order in which, for each of the readout data, after all of the first encoding target data in the readout data and the first error correction code corresponding to the first encoding target data are read out, the second error correction code in the readout data is read out.

5. The semiconductor storage device according to claim 2, wherein the second encoding target data includes an octet of the first unit data.

6. The semiconductor storage device according to claim 3, wherein the readout determining unit sets the second error correction code read out last in the readout unit data as the second error correction code for determining whether to be read out from the nonvolatile semiconductor memory.

7. The semiconductor storage device according to claim 3, wherein the readout determining unit sets all the second error correction codes in the readout unit data as the second error correction code for determining whether to be read out from the nonvolatile semiconductor memory.

8. The semiconductor storage device according to claim 6, wherein the readout determining unit determines that the second error correction code read out in a position other than the last in the readout unit data is read out when a required time for reading out the second error correction code is equal to or shorter than a required time of processing for, after stopping readout before readout of the second error correction code, resuming the readout immediately after the second error correction code.

9. The semiconductor storage device according to claim 1, further comprising a skip instructing unit that instructs, for each of the readout unit data, when there is no instruction from the readout determining unit, the readout control unit to read out the readout unit data stored in the nonvolatile semiconductor memory excluding the second error correction code, wherein
the readout determining unit determines, when the first error correction processing unit determines that there is a remaining error in the write data in the readout unit data read out excluding the second error correction code, that the second error correction code of the readout unit data is read out and instructs the skip instructing unit to read out the second error correction code,
the skip instructing unit instructs, based on the instruction from the readout determining unit, the readout control unit to read out the readout unit data, the second error correction code of which is instructed to be read out, from the nonvolatile semiconductor memory as re-readout data including the second error correction code,
the readout control unit performs control, based on the instruction from the skip instructing unit, to read out the readout data excluding the second error correction code or the re-readout data from the nonvolatile semiconductor memory, and
the second error correction processing unit carries out the second error correction processing for the write data using the re-readout data.

10. The semiconductor storage device according to claim 1, wherein the nonvolatile semiconductor memory is a NAND flash memory.

11. The semiconductor storage device according to claim 1, further comprising an error detection processing unit that determines, based on the write data and the error detection signal read out from the nonvolatile semiconductor memory, whether there is an error in the write data, wherein
the readout determining unit further determines, based on a result of determination by the error detection processing unit concerning the write data in the first encoding target data, whether the first error correction code corresponding to the first encoding target data is read out from the nonvolatile semiconductor memory.

12. A semiconductor storage device comprising:
a nonvolatile semiconductor memory;
a writing processing unit that writes, in the nonvolatile semiconductor memory, write data having a predetermined size, an error detection code generated to detect an error in the write data, and an error correction code generated to correct an error in encoding target data including the write data and the error detection code corresponding to the write data;
an error detection processing unit that determines, based on the write data and the error detection code read out from the nonvolatile semiconductor memory, whether there is an error in the write data;
an error correction processing unit that carries out error correction processing for the write data using the encoding target data including the write data determined as having the error by the error detection processing unit and the error correction code read out from the nonvolatile semiconductor memory;
a readout determining unit that determines, based on a determination result by the error detection processing unit for the write data in the encoding target data, whether the error correction code corresponding to the encoding target data is read out from the nonvolatile semiconductor memory; and
a readout control unit that controls, based on a result of the determination by the readout determining unit, readout from the nonvolatile semiconductor memory.

13. The semiconductor storage device according to claim 1, wherein the error correction code is a CRC16 code or a CRC36 code.

14. The semiconductor storage device according to claim 1, wherein the first error correction code is a hamming code.

15. The semiconductor storage device according to claim 1, wherein the second error correction code is a BCH code.

16. The semiconductor storage device according to claim 1, wherein the second error correction code is a Reed-Solomon code.

17. The semiconductor storage device according to claim 1, wherein the second error correction code is an LDPC code.

18. The semiconductor storage device according to claim 1, wherein the first error correction processing unit determines, using syndrome calculation and Chien search, whether there is an error remaining in the write data after the first error correction processing.

19. The semiconductor storage device according to claim 1, wherein the predetermined size is 512 bytes.

20. A control method for a semiconductor storage device, comprising:
writing, in the nonvolatile semiconductor memory, write data having a predetermined size, an error detection code generated to detect an error in the write data, a first error correction code generated to correct an error in first encoding target data including the write data and the error detection code corresponding to the write data, and a second error correction code generated to correct an error in a second encoding target data including a singularity or a plurality of the first encoding target data;
carrying out first error correction processing for the write data using the write data, the error detection code, and the first error correction code read out from the nonvolatile semiconductor memory and determining whether there is an error remaining in the write data after the first error correction processing;
carrying out second error correction processing for the write data using the second encoding target data including the write data determined as having the remaining error after the first error correction processing and the second error correction code read out from the nonvolatile semiconductor memory;
determining, based on a result of the determination concerning whether there is an error remaining in the write data after the first error correction processing, whether the second error correction code corresponding to the second encoding target data is read out from the nonvolatile semiconductor memory; and
controlling, based on a result of the determination concerning whether the second error correction code corresponding to the second encoding target data is read out from the nonvolatile semiconductor memory, readout from the nonvolatile semiconductor memory.
